(19) United States
(12) Patent Application Publication
(10) Pub. No.: US 2006/0094233 A1
(43) Pub. Date: May 4, 2006

(54) Device and method for determining an edge coverage during coating processes

(76) Inventors: Martin Gutsche, Dorfen (DE); Harald Seidl, Poring (DE)

Correspondence Address: JENKINS, WILSON & TAYLOR, P. A., 3100 TOWER BLVD, SUITE 1200, DURHAM, NC, 27707, US

(21) Appl. No.: 11/256,300

(22) Filed: Oct. 21, 2005

(30) Foreign Application Priority Data
Oct. 29, 2004 (DE) 102004052626.5

(51) Int. Cl. H01L 21/4763

(52) U.S. Cl. 438/637

(57) ABSTRACT

In a method for determining an edge coverage during coating processes a substrate is provided, a mask layer is deposited on the substrate, at least one through hole is formed in the mask layer and at least one first trench-type depression is formed in the substrate by patterning the substrate and the mask layer. An expanded second trench-type depression which extends in a direction parallel to the surface of the substrate is obtained by expanding isotropically the first trench-type depression. The second trench-type depression comprises a lateral trench opening at at least one lateral end region so that a coating material can penetrate laterally into the second trench-type depression through the trench opening.

### BACKGROUND OF THE INVENTION

1. Field of the Invention

The present invention relates to coating processes for coating microtechnical structures, in particular during the production of circuit units, and relates in particular to a method for determining an edge coverage (also referred to as edge covering or degree of edge covering) during coating processes, and to a corresponding device.

2. Description of the Related Art

Specifically, the present invention relates to a method for determining an edge coverage, a substrate being provided, a mask layer being deposited on the substrate, the substrate and the mask layer deposited on the substrate being patterned lithographically in such a way that at least one through hole (or a longitudinal groove) is formed in the mask layer deposited on the substrate and at least one first trench-type depression is formed in the substrate, the first trench-type depression being expanded isotropically in such a way that an expanded second trench-type depression is obtained, and a covering layer being deposited in such a way that the through hole formed in the mask layer is closed. In other words, an elongate tunnel is formed in the substrate.

The problem of edge coverage arises in physical and/or chemical vapor deposition processes. Particularly when very thin layers are applied, the disadvantage that results is that edges in the case of microtechnical structures cannot be covered sufficiently and structures having a high aspect ratio cannot be covered as far as the bottom. It is absolutely necessary to evaluate a coating process with regard to the edge coverage. For this purpose, it is necessary to provide a test method for determining an edge coverage which can make a prediction about the quality of a coating process to be used and/or serves for production-accompanying monitoring. Coating processes of this type include, inter alia:

(i) physical vapor deposition (PVD) processes;

(ii) chemical vapor deposition (CVD) processes; and/or

(iii) atomic layer deposition (ALD) processes.

In order to determine the degree of an edge coverage during deposition processes generally from the vapor phase, test structures having an aspect ratio are required. This applies particularly to ALD (atomic layer deposition) processes. It is disadvantageous that in many cases no etching processes exist that can be used to realize the vertical structures with such large aspect ratios.

For determining the edge coverage, the prior art has proposed etching vertical holes having a high aspect ratio into silicon. It is disadvantageous that such etching processes in silicon require very complicated trench etching procedures (Trench Etch Processes).

### SUMMARY OF THE INVENTION

It is an object of the present invention to provide a method and a device for determining an edge coverage during coating processes which are relatively simple and cost-effective and which do not require structures having a high aspect ratio.

The object is achieved in accordance with the invention by dispensing with vertical structures in silicon wafers or structures having high aspect ratios by forming trenches laterally, extending parallel to a silicon (wafer) surface, which trenches are covered from above with a covering layer and opened laterally. This affords the advantage that it is possible to estimate an edge coverage on the basis of a penetration of coating material into one lateral opening of the trenches (or both lateral openings of the trenches).

Preferably, the trench-type depressions may be oriented in a direction parallel to the surface of the substrate, the trench-type depressions having a trench opening at at least one lateral end region, through which trench opening the coating material can penetrate laterally into the trench-type depression.

This affords the advantage that, in the case of arranging parallel trenches offset in the lateral direction, in a cross section through the wafer, an edge coverage can be estimated in a simple manner.

In accordance with one general aspect, the inventive method for determining an edge coverage during coating processes essentially has the following steps:

a) provision of a substrate;

b) deposition of a mask layer on the substrate;

c) patterning of the substrate and of the mask layer deposited on the substrate lithographically in such a way that at least one through hole is formed in the mask layer deposited on the substrate and at least one first trench-type depression is formed in the substrate;

d) isotropic expansion of the first trench-type depression in such a way that an expanded second trench-type depression is obtained; and

e) deposition of a covering layer in such a way that the through hole formed in the mask layer is closed, the second trench-type depression extending in a direction parallel to the surface of the substrate, and having a lateral trench opening at at least one lateral end region, through which trench opening a coating material can penetrate laterally into the second trench-type depression.

The object is also achieved in accordance with the invention by a device for determining an edge coverage during the coating processes, comprising:

a) a substrate;

b) a mask layer deposited on the substrate, the substrate and the mask layer deposited on the substrate being patterned lithographically in such a way that at least one through hole is formed in the mask layer deposited on the substrate and at least one trench-type depression is formed in the substrate; and

c) a covering layer deposited in such a way that the through hole formed in the mask layer is covered, the trench-type depression extending in a direction parallel to the surface of the substrate and the trench-type depression having a lateral trench opening at at least one lateral end region, through which trench opening a coating material can penetrate laterally into the trench-type depression.

The deposition of the mask layer may be carried out by means of chemical vapor deposition (CVD) and/or by means of physical vapor deposition (PVD) and/or by means of atomic layer deposition (ALD).

The isotropic expansion of the first trench-type depression may be carried out in such a way that an expanded second trench-type depression is obtained selectively with respect to the mask layer deposited on the substrate. For this purpose, use is preferably made of an isotropic etching process either wet-chemically or dry-chemically.

The deposition of the covering layer is effected either conformally or non-conformally. In accordance with yet another preferred development of the present invention, the deposition of the covering layer is carried out by means of chemical vapor deposition (CVD) and/or by means of physical vapor deposition (PVD) and/or by means of atomic layer deposition (ALD).

In a restricted version of the inventive method, the substrate is provided as a silicon wafer (Si), and the mask layer is provided for example from silicon dioxide (SiO₂).

The mask layer may be formed as a hard mask. The mask layer preferably comprises a silicon nitride material (Si₃N₄). The covering layer may preferably be provided from a silicon oxide material (SiO₂) or a silicon nitride material (Si₃N₄) or an aluminum oxide material (Al₂O₃)

At least two trench-type depressions may be formed in parallel fashion and in a manner offset in the longitudinal direction in the substrate.

For determining the edge coverage in a simplified manner, the at least two trench-type depressions are arranged parallel and in a manner offset in each case by a constant amount with respect to one another in the longitudinal direction.

Respective lateral trench openings may be provided at both lateral end regions of the trench-type depression.

In this way, it is possible to obtain a method and a device which enable an edge coverage during coating processes in a simple and cost-effective manner without having to etch deep structures having a high aspect ratio into the substrate.

### DESCRIPTION OF THE DRAWINGS

FIGS. 1(a) to (d) show process steps for producing a covered trench-type depression running in the substrate in accordance with a preferred exemplary embodiment of the present invention;

FIG. 2 is a plan view of four exemplary trench-type depressions which are offset relative to one another and produced by means of the production steps described in FIG. 1(a) to FIG. 1 (d); and

FIG. 3 is a device for determining an edge coverage during coating processes on the basis of a series of trench structures offset in the longitudinal direction in accordance with the preferred exemplary embodiment of the present invention.

### DESCRIPTION OF THE PREFERRED EMBODIMENTS

In the figures, identical reference symbols designate identical or functionally identical components or steps.

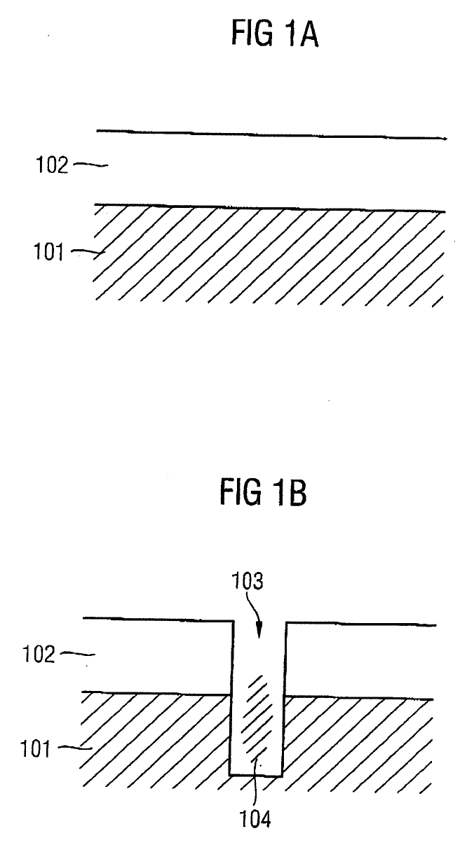

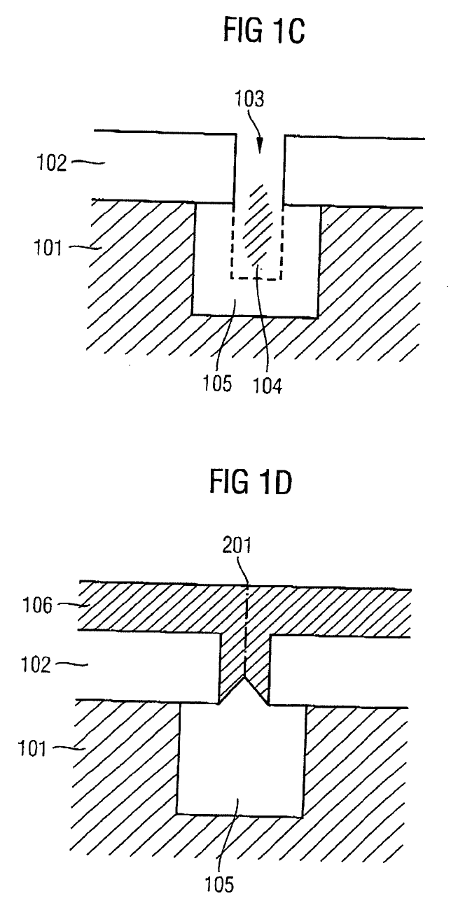

FIGS. 1(a), (b), (c) and (d) illustrate sectional views through a trench structure formed by the method according to the invention. Specifically, FIG. 1(a) shows a cross section through a substrate 101, to which a mask layer 102 is applied (steps a) and b) of the method described above).

FIG. 1(b) shows a cross section through the structure shown in FIG. 1(a) after a lithography step, in such a way that the substrate 101 and the mask layer 102 deposited on the substrate are patterned lithographically in a manner such that a through hole 103 (or an elongate slot or a longitudinal groove) is formed in the mask layer 102 deposited on the substrate 101 and a trench-type depression 104 (first trench-type depression) is formed in the substrate 101. In this case, the mask layer 102 or a further resist mask serves as a mask for patterning the first trench-type depression 104.

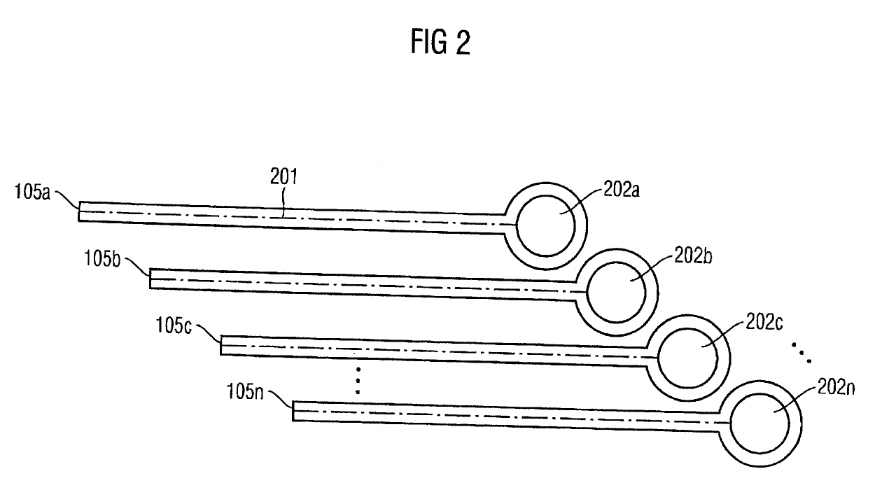

FIG. 1(c) shows a subsequent process step, by means of which an isotropic expansion of the first trench-type depression 104 has been provided in such a way that an expanded second trench-type depression 105 is obtained. The first trench-type depression 104 is indicated by dashed lines in FIG. 1(c). It should be pointed out that, in accordance with the method according to the invention for determining an edge coverage during coating processes, the first and second trench-type depressions 104, 105 are not structures having a high aspect ratio, that is to say that the trenches extend longitudinally as so-called “tunnels” in a lateral direction parallel to the surface of the substrate, and the trench-type depressions are extended substantially further in a longitudinal direction than in a depth direction, as will be illustrated below with reference to FIG. 2.

FIG. 1(d) shows the with a covering layer 106 deposited on the structures formed in FIG. 1(c), said covering layer being deposited in such a way that the through hole 103 formed in the mask layer 102 is closed. In this case, the through hole 103 grows over from the edges of the mask layer 102, to be precise symmetrically with respect to a trench center (trench center line) 201. Conformal and non-conformal deposition processes are preferably used for this purpose.

FIG. 2 shows a plan view of the substrate, illustrating the second trench-type depressions 105a-105n lying below the mask layer 102 and the covering layer 106. As can be seen from FIG. 2, a number of n second trench-type depressions 105a-105n running parallel to one another are provided, the second trench-type depressions 105a-105n in each case being offset with respect to one another in the longitudinal direction. A lateral trench opening 202a-202n is in each case provided at one end of the trench-type depressions 105a-105n. In terms of its dimensions (diameter), said lateral trench opening is substantially larger than the cross section of the second trench-type depression 105a-105n (see FIG. 1(d)).

If a deposition is then effected onto the substrate, that is to say onto the structure shown in FIG. 2, then depending on the edge coverage capability of the coating material, a coating material will penetrate through the lateral trench openings 202a-202n of the second trench-type depressions 105a-105n and laterally into the second trench-type depressions 105a-105n.

It should be pointed out that, although this is not illustrated in FIG. 2, the second trench-type depressions may have lateral trench openings 202a-202n at both lateral end regions.

Depending on the edge coverage capability—that is to say depending on the magnitude of the sticking coefficient—of the coating process, the coating material used in a test penetrates more or less laterally into the second trench-type depressions 105-105n which are in each case covered with the covering layer 106. The penetration of coating material into the tunnel (channel) open toward one side thus represents a measure of the edge coverage capability of the coating process.

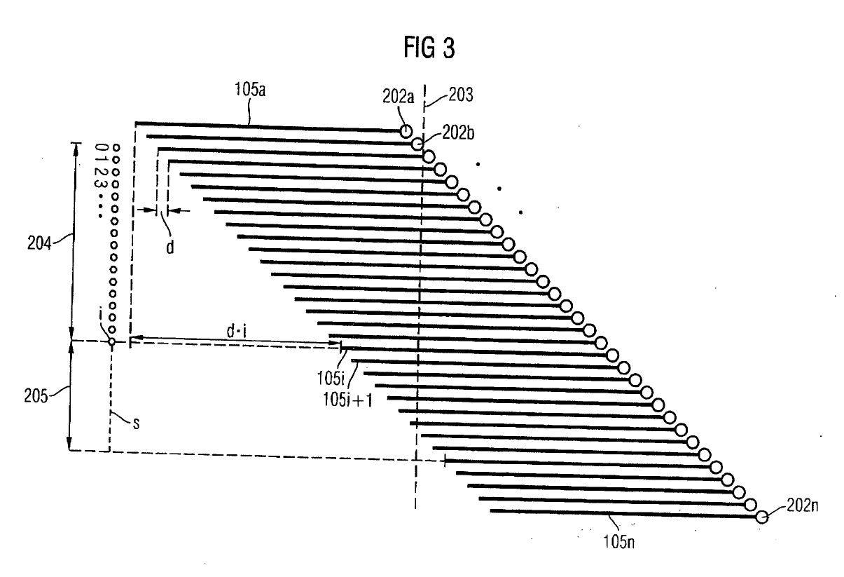

FIG. 3 shows a device for determining an edge coverage during coating processes in accordance with a preferred exemplary embodiment of the present invention. As shown in FIG. 3, the individual second trench-type depressions 105a-105n each have the same length, the lateral trench openings 202a-202n in each case being arranged at one end (right-hand end in FIG. 3) of the second trench-type depressions 105a-105n. As illustrated in FIG. 3, the second trench-type depressions 105a-105n are offset in each case by an offset amount d with respect to one another in the trench longitudinal direction. This means that, depending on the deposition process, it is possible to ascertain a deposition up to a specifically measurable second trench-type depression 105i if a section, i.e. a break line 203, is made through the wafer (the substrate 101).

FIG. 3 illustrates that a coating up to the second trench-type depression No. 105i is ascertained. This results in a deposition region 204, in which, in a cross section along the break line 203, it is possible to ascertain a deposition in the trench-type depressions 105a, 105b, . . . , 105i, while no coating is ascertained in the trench-type depressions 105i+1, 105i+2, 105i+3, . . . , 105n, that is to say that these trench-type depressions are situated in a deposition-free region 205. The sequential number i up to which a coating in the second trench-type depressions 105a-105n is ascertained corresponds to an edge coverage capability of the coating process under investigation.

In this way, the method according to the present invention avoids complicated “trench etch processes” which are associated with etching vertical holes into a substrate. The device according to the invention has substantially shallow, but in return very long trenches which are etched into the substrate 101 and subsequently covered with the covering layer 106. This gives rise to long tunnels which are used, during an ALD, CVD and/or PVD deposition, to determine the edge coverage capability of the coating process.

The ascertaining of the depth or the sequential number i of a second trench-type depression 105a-105n up to which a coating has taken place is known to the person skilled in the art. For this purpose, the person skilled in the art uses for example a wafer breaking technique with subsequent SEM (scanning electron microscopy) examination. For this reason, such an examination method is not discussed in the present invention.

It should be pointed out, however, that through the possibility of using standardized SEM (scanning electron microscopy) methods, an investigation of the edge coverage capability of coating processes is facilitated and/or can be standardized. What is used as a measure of the deposition depth, as illustrated in FIG. 3, is the lateral offset amount multiplied by the number of that second trench-type depression 105i at which it is precisely still possible to ascertain a coating in the cross section of the break line 203.

Although modifications and changed may be suggested by those skilled in the art, it is the intention of the inventors to embody within the patent warranted heron all changes and modifications as reasonable and properly come within the scope of their contribution to the art.

We claim as our invention:

1. A method for determining an edge coverage during coating processes, comprising the steps of:
providing a substrate;
depositing a mask layer on said substrate;
forming at least one through hole in said mask layer and at least one first trench-type depression in said substrate by patterning said substrate and said mask layer being deposited on said substrate;
obtaining an expanded second trench-type depression which extends in a direction parallel to the surface of said substrate by expanding isotropically said first trench-type depression; said second trench-type depression comprising a lateral trench opening at at least one lateral end region so that a coating material can penetrate laterally into said second trench-type depression through said trench opening; and
closing said through hole formed in said mask layer by depositing a covering layer.

2. The method of claim 1, comprising carrying out said depositing of said mask layer by chemical vapor deposition, physical vapor deposition or atomic layer deposition.

3. The method of claim 1, comprising obtaining said expanded second trench-type depression by expanding isotropically said first trench-type depression selectively with respect to said mask layer deposited on said substrate.

4. The method of claim 3, comprising expanding said first-type depression by means of a wet-chemical or dry-chemical isotropic etching process.

5. The method of claim 1, comprising depositing said covering layer conformally or non-conformally.

6. The method of claim 1, comprising depositing said covering layer by chemical vapor deposition, physical vapor deposition or atomic layer deposition.

7. The method of claim 5, comprising depositing said covering layer by chemical vapor deposition, physical vapor deposition or atomic layer deposition.

8. A device for determining an edge coverage during coating processes, comprising:
a substrate having at least one trench-type depression;
a mask layer which is deposited on said substrate and comprises at least one through hole; and
a covering layer which covers said through hole formed in said mask layer;
said at least one through hole and said at least one trench-type depression have been formed in said substrate and said mask-layer, respectively, by patterning lithographically said substrate and said mask layer; said trench-type depression extending in a direction parallel to the surface of said substrate; and said trench-type depression comprising a lateral trench opening at at least one lateral end region so that a coating material can penetrate laterally into said trench-type depression through said trench opening.

9. The device of claim 8, wherein said substrate is provided as a silicon wafer.

10. The device of claim 8, wherein said mask layer is provided as a hard mask.

11. The device of claim 10, wherein said mask layer is provided from a silicon nitride material.

12. The device of claim 8, wherein said covering layer is formed from a silicon oxide material, a silicon nitride material or an aluminum oxide material.

13. The device of claim 8, comprising at least two trench-type depressions being formed in parallel fashion and in a manner offset in the longitudinal direction in said substrate.

14. The device of claim 13, wherein said at least two trench-type depressions are arranged parallel and in a manner offset in each case by a constant amount with respect to one another in said longitudinal direction.

15. The device of claim 8, wherein respective of said lateral trench openings are provided at both of said lateral end regions of said trench-type depression.
